(19) United States
(12) Patent Application Publication
(10) Pub. No.: US 2008/0179711 A1
(43) Pub. Date: Jul. 31, 2008

(54) SUBSTRATE AND SEMICONDUCTOR DEVICE USING THE SAME

(75) Inventors: Hiroaki Fujimoto, Osaka (JP); Kenichi Imazu, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/937,847

(22) Filed: Nov. 9, 2007

(30) Foreign Application Priority Data
Nov. 20, 2006 (JP) 2006-312316

(51) Int. Cl. H01L 23/48

(52) U.S. Cl. 257/620; 257/E23.01

(57) ABSTRACT

According to the present invention, a plurality of semiconductor devices having semiconductor chips 13 molded on a semiconductor package substrate 1 by a molding resin 15 can be manufactured by forming recesses 10 around each semiconductor package substrate 1 composing a substrate 8 for a BGA package, and in the state where a molding resin 15 is filled on the substrate 8 including the recesses 10 for resin molding, cutting the substrate 8 and the molding resin 15 along partition lines 9.

### FIELD OF THE INVENTION

The present invention relates to a substrate consisting of a plurality of semiconductor package substrates on which semiconductor chips are mounted used in a BGA package and the like, and a semiconductor device using such a substrate.

### BACKGROUND OF THE INVENTION

In recent years, in order to cope with the size reduction of electronic devices such as mobile communication apparatuses, size reduction and high integration are also required in semiconductor devices. As the high functionality and multi-functionality of electronic devices have advanced, BGA packages and LGA packages for semiconductor devices whose external terminals tend to have a large number of pins and are disposed on the bottom surface of the package in an area array form are frequently used.

Such semiconductor devices are obtained, for example, in a state where semiconductor chips are molded with a molding resin on each semiconductor package substrate composing a substrate for a BGA package, by cutting the substrate and the molding resin into individual semiconductor package substrates.

A method for manufacturing a conventional semiconductor device (for example, refer to Japanese Patent Application Laid-Open No. 2001-274283) exemplified by a BGA package will be described.

FIG. 7 is a top view showing a state where a wiring pattern is formed on a conventional substrate for a BGA package; FIGS. 8A to 8D are sectional views showing manufacturing steps in the method for manufacturing a conventional semiconductor device; and FIG. 9 is a sectional view showing the appearance of a semiconductor device manufactured using the manufacturing steps in the method for manufacturing a conventional semiconductor device.

Firstly, as shown in FIGS. 7 and 8A, a substrate 8 having a plurality of semiconductor package substrates 1 partitioned by partition lines 9 is prepared. Here, as the substrate 8, the case where six semiconductor package substrates 1 are formed vertically and horizontally by the partition lines 9 is shown. The plurality of semiconductor package substrates 1 composing the substrate 8 consist of insulating substrates, such as a glass-epoxy substrates. On the surface of each semiconductor package substrate, a semiconductor chip mounting region 2, internal electrodes 3, conductor wirings 4, and wirings for plating 5 are formed. On the back face, external electrodes 16 for external connection are formed, and although not shown in the drawings, the conductor wirings 4 are electrically connected to the external electrodes 16 via through-holes and the like formed in the substrate 8.

Next, as shown in FIG. 8B, a semiconductor chip 13 is adhered with a conductive resin on each of a plurality of semiconductor chip mounting regions 2 formed on the surface of the substrate 8. Then, the electrode of each semiconductor chip 13 is electrically connected to each internal electrode 3 with a bonding wire 14 of Au and the like.

Next, as shown in FIG. 8C, the entire region of the surface of the substrate 8 is molded with a molding resin 15 consisting of an epoxy resin and the like.

Next, as shown in FIG. 8D, the substrate 8 and the molding resin 15 are divided by the partition lines 9 by cutting the substrate 8 and the molding resin 15 along the partition lines 9 using a dicing saw and the like, to obtain a plurality of semiconductor devices wherein the semiconductor chip 13 is molded with the molding resin 15 on the semiconductor package substrate 1.

However, by such a conventional semiconductor device and a method for manufacturing the conventional semiconductor device, when the substrate 8 and the molding resin 15 are divided into a plurality of semiconductor devices, the wiring for plating 5 is divided at the same time, and as shown in FIG. 9, the end surface of the wiring for plating 5 is exposed on the side of the semiconductor device.

If the wiring for plating 5 is exposed on the side of a semiconductor device, a socket for testing, a pickup tool for mounting electronic devices on a printed circuit board and the like may contact the wiring for plating 5 during subsequent testing steps and when the electronic devices are mounted on the printed circuit board, and in those cases, the wiring for plating 5 may be deformed and electrical short-circuiting may occur between adjoining wirings for plating 5. Further, the deposition of impurity ions and the moisture absorption of the semiconductor device may cause migration on the side. Therefore, the semiconductor device has disadvantageously lowered reliability.

Since substantially all the internal wirings 3 were electrically connected (short-circuited) by the wiring for plating 5 until the substrate 8 and the molding resin 15 were cut along the partition lines 9 into individual semiconductor devices, electrical testing of individual semiconductor package substrates 1 in the state of the substrate 8 was difficult, and a semiconductor chip 13 may be mounted on a defective semiconductor package substrate 1, eventually lowering productivity of the semiconductor devices.

### DISCLOSURE OF THE INVENTION

To solve such conventional problems, an object of the present invention is to provide a substrate that can improve the reliability and productivity of semiconductor devices, and a semiconductor device using such a substrate.

To solve such problems, a substrate according to the present invention includes a plurality of semiconductor package substrates on the surface of which electrically connected internal electrodes and semiconductor chip mounting regions for mounting conductor wirings and semiconductor chips are formed; wherein recesses are formed on the periphery of each semiconductor package substrate, the internal electrodes are electrically insulated from the conductor wirings between the individual semiconductor package substrates; and the recesses are formed in a trench shape except on the corner portions of the peripheries of the semiconductor package substrates.

In another semiconductor device according to the present invention, semiconductor chips are mounted in semiconductor chip mounting regions on a substrate comprising a plurality of semiconductor package substrates on the surface of which electrically connected internal electrodes and semiconductor chip mounting regions for mounting conductor wirings and semiconductor chips are formed; the electrodes of the semiconductor chips are electrically connected to the internal electrodes; thin portions are formed on the periphery of each of the semiconductor package substrates; all the regions including at least the thin portions other than the semiconductor chip mounting regions in the semiconductor package substrates are coated with a molding resin; and the thin portions are formed in a trench shape except on the corner portions in the peripheries of the semiconductor package substrate.

According to the present invention, as described above, recesses are formed in the peripheral portion of each semiconductor package substrate in the substrate, and since the warpage of each semiconductor package substrate can be relieved by the recesses and the warpage of the entire substrate can be reduced, the mounted quality, when a semiconductor chip is mounted on each semiconductor package substrate in the subsequent steps of forming the substrate, can be improved.

Since the internal conductor portions are not exposed on the side of the semiconductor device formed with resin molding performed after mounting semiconductor chips on each semiconductor package substrate as in the conventional way, the occurrence of short-circuiting and migration between conductors can be avoided; and since the side of the semiconductor device is only the interface between the molding resin having high adhesiveness and the base material of the semiconductor package substrate, the invasion of moisture into the semiconductor device from outside can also be minimized.

Thereby, the reliability of the semiconductor device can be improved, and the expansion of applications, such as on-board systems used in a harsh environment, can be realized.

In addition, since all the internal wirings are insulated from each other by the recesses formed in the peripheral portion of each semiconductor package substrate, and wiring patterns on individual semiconductor package substrates can be electrically tested even in the state of a substrate, only conforming semiconductor package substrates can be correctly selected and mounted with semiconductor chips.

As a result, the reliability of the semiconductor device can be improved, and the productivity thereof can also be improved.

### BRIEF DESCRIPTION OF THE DRAWINGS

FIG. 1 is a top view showing a state where a wiring pattern is formed on a substrate according to an embodiment of the present invention;

FIG. 2 is a top view showing a state where trench-shaped recesses are formed on the peripheral portion of each semiconductor package substrate in the substrate according to the embodiment;

FIG. 3 is a top view showing a state where ring-shaped recesses are formed on the peripheral portion of each semiconductor package substrate in the substrate according to the embodiment;

FIG. 4 is a top view showing a state where independent recesses are formed on the peripheral portion of each semiconductor package substrate in the substrate according to the embodiment;

FIG. 5A is a sectional view showing a manufacturing step 1 in a method for manufacturing a semiconductor device according to the embodiment;

FIG. 5B is a sectional view showing a manufacturing step 2 in the method for manufacturing the semiconductor device according to the embodiment;

FIG. 5C is a sectional view showing a manufacturing step 3 in the method for manufacturing the semiconductor device according to the embodiment;

FIG. 5D is a sectional view showing a manufacturing step 4 in the method for manufacturing the semiconductor device according to the embodiment;

FIG. 6 is a side view showing the appearance of the semiconductor device manufactured by the manufacturing steps in the method for manufacturing the semiconductor device according to the embodiment;

FIG. 7 is a top view showing a state where a wiring pattern is formed on a conventional substrate for a BGA package;

FIG. 8A is a sectional view showing a manufacturing step 1 in a method for manufacturing a semiconductor device according to a conventional embodiment;

FIG. 8B is a sectional view showing a manufacturing step 2 in the method for manufacturing the semiconductor device according to the conventional embodiment;

FIG. 8C is a sectional view showing a manufacturing step 3 in the method for manufacturing the semiconductor device according to the conventional embodiment;

FIG. 8D is a sectional view showing a manufacturing step 4 in the method for manufacturing the semiconductor device according to the conventional embodiment; and

FIG. 9 is a side view showing the appearance of the semiconductor device manufactured by the manufacturing steps in the method for manufacturing the semiconductor device according to the conventional embodiment.

### DESCRIPTION OF THE EMBODIMENTS

A substrate and a semiconductor device using such a substrate according to an embodiment of the present invention will be specifically described referring to the drawings.

The substrate according to the embodiment of the present invention will be described.

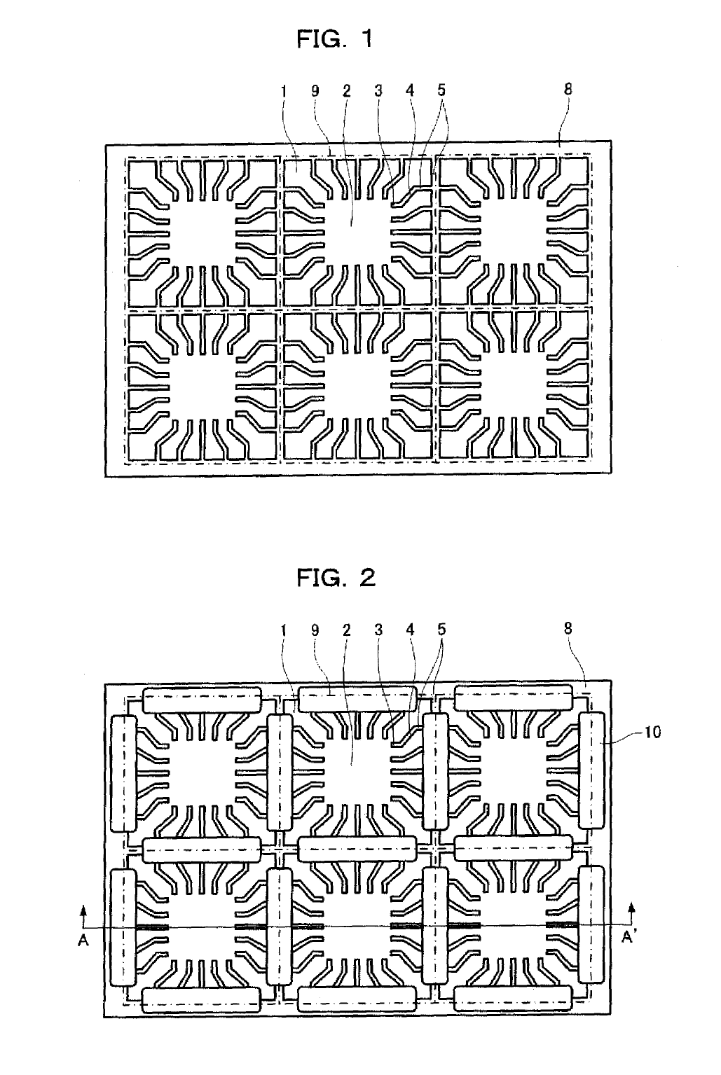

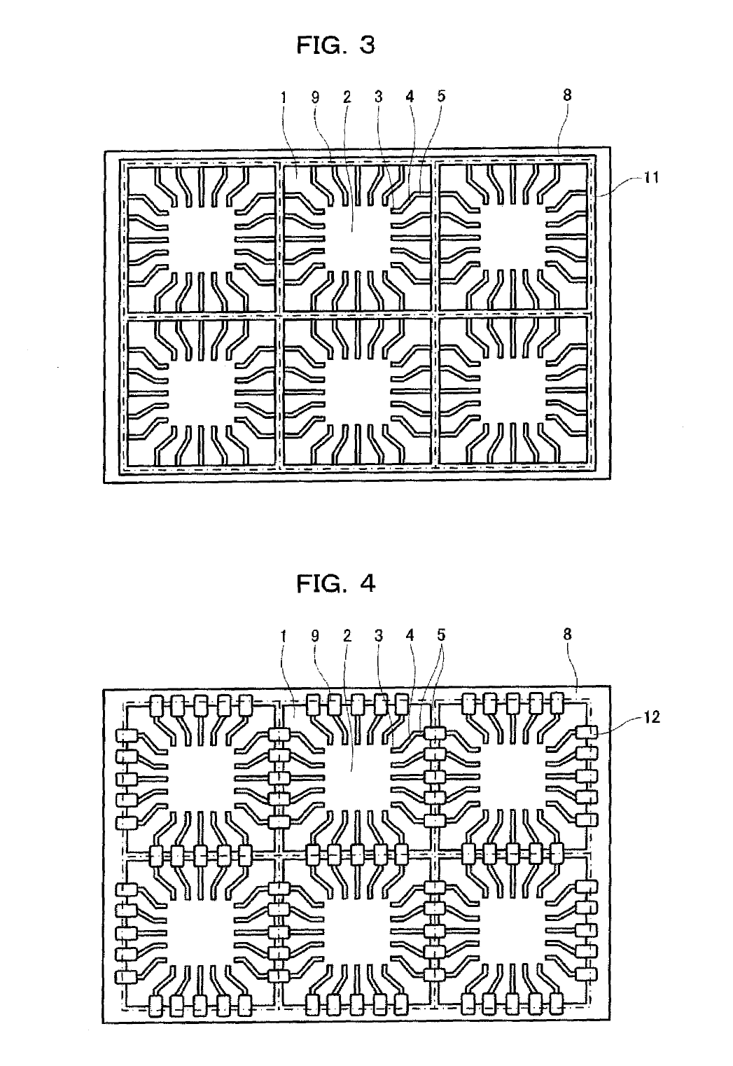

FIG. 1 is a top view showing a state where a wiring pattern is formed on the substrate according to the embodiment of the present invention; FIG. 2 is a top view showing a state where trench-shaped recesses are formed on the peripheral portion of each semiconductor package substrate only in a region of wirings for plating in the substrate according to the embodiment; FIG. 3 is a top view showing a state where ring-shaped recesses are formed on the entire peripheral portion of each semiconductor package substrate in the substrate according to the embodiment; and FIG. 4 is a top view showing a state where independent recesses for each wiring for plating are formed on the peripheral portion of each semiconductor package substrate in the substrate according to the embodiment.

In FIG. 1, the base materials of the substrate 8 for a BGA or LGA package are glass-epoxy, BT resin, polyimide and the like, and the thickness thereof is about 0.1 mm to 0.8 mm. The substrate 8 is composed of a plurality of semiconductor package substrates 1, and individual semiconductor package substrates 1 are partitioned by partition lines 9. Each semiconductor package substrate 1 has internal electrodes 3, conductor wirings 4, and wirings for plating 5 formed on the surface thereof. Although not shown in the drawing, the semiconductor package substrate 1 has an external electrode formed on the back face thereof, which are electrically connected to the internal electrodes 3 via through-holes and the like formed in the substrate 8.

The material for the main conductors of the internal electrodes 3, the conductor wirings 4, and the wirings for plating 5 is normally Cu, and the main conductors are formed using etching, plating, and the like. The thickness of the main conductor is about 5 to 35 μm. The internal electrodes 3 are regions later electrically connected to the electrodes of the semiconductor chip with Au bonding wires, and for improving the bondability, the internal electrodes 3 are normally subjected to Ni/Au plating by an electrolytic method. The wirings for plating 5 are connected at this time to the electrodes for plating.

Next, as shown in FIG. 2, trench-shaped recesses 10 are formed only in the wiring portions for plating in the periphery of each semiconductor package substrate 1. The trench-shaped recesses 10 are formed by mechanical cutting using a router and the like, or by a laser and the like. At this time, the wirings for plating 5 are also cut, and the conductor wirings 4 are electrically isolated from each other.

The depth of the recesses 10 is about 10% to 90% of the thickness of the substrate 8 (or the semiconductor package substrate 1), and is determined by the thickness of the substrate 8 (or the semiconductor package substrate 1). The width of the recesses 10 is about 50 μm to 500 μm. The recesses 10 can be substituted by ring-shaped recesses 11 extending throughout the periphery of each semiconductor package substrate 1 in the substrate 8 as shown in FIG. 3. Alternatively, an independent recess 12 may be formed for each of the wirings for plating 5 on the periphery of each semiconductor package substrate 1 in the substrate 8 as shown in FIG. 4.

Now, a semiconductor device and a method for manufacturing such a semiconductor device according to the embodiment of the present invention will be described.

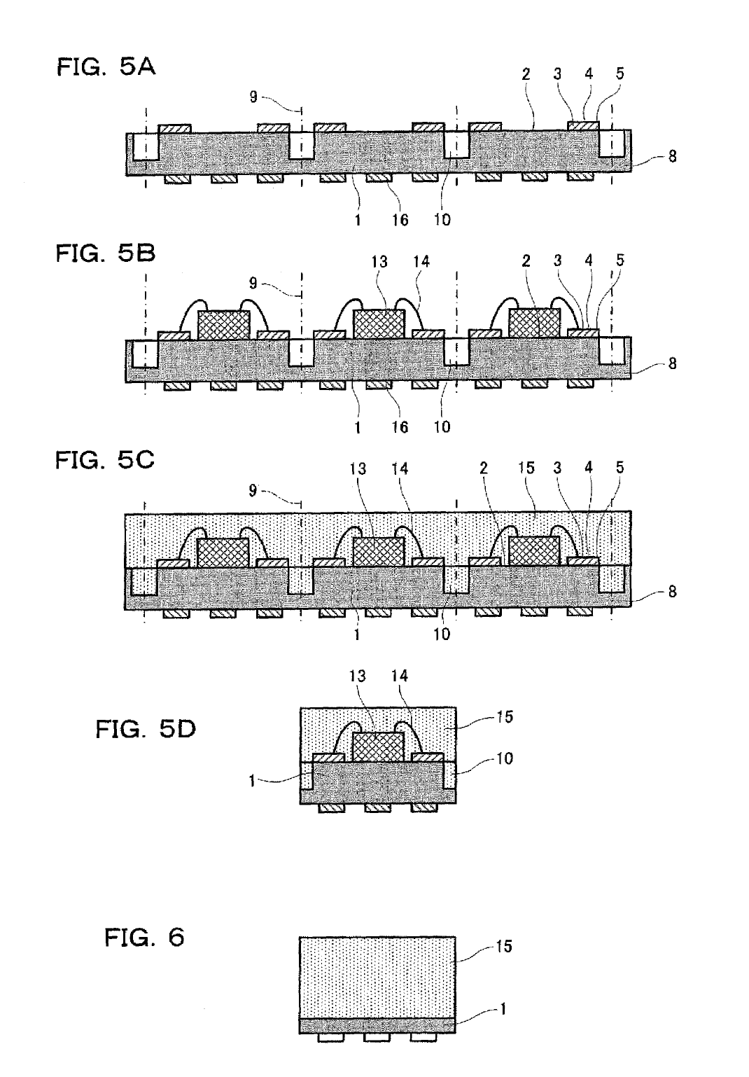

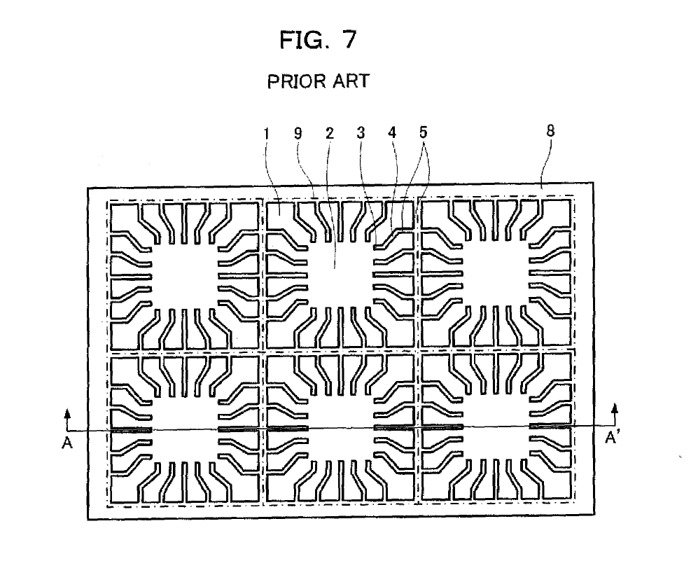

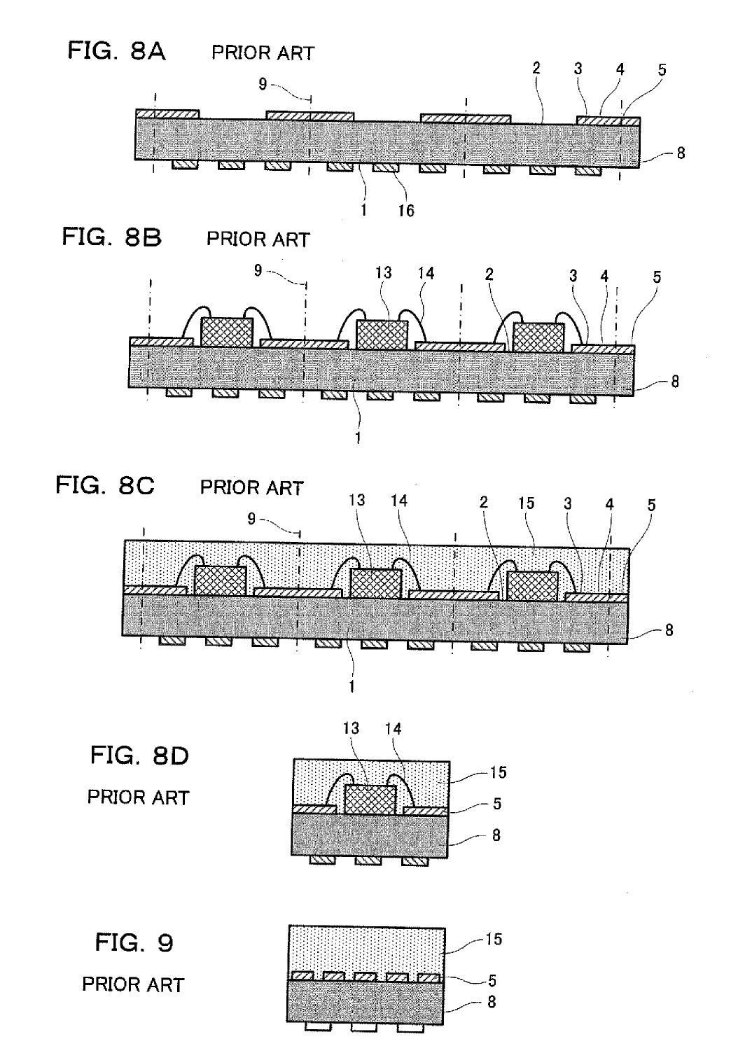

FIGS. 5A to 5D are sectional views showing manufacturing steps in the method for manufacturing the semiconductor device according to the present embodiment; and FIG. 6 is a side view showing the appearance of a semiconductor device manufactured by the manufacturing steps in the method for manufacturing the semiconductor device according to the present embodiment.

FIG. 5A is a sectional view of the substrate 8 shown in FIG. 2 taken along the line A-A′. As shown in FIG. 5A, the substrate 8 is composed of a plurality of semiconductor package substrates 1. Each semiconductor package substrate 1 has a semiconductor chip mounting region 2, the internal electrodes 3, and the conductor wirings 4 on the surface thereof; and has external electrodes 16 connected to external wirings on the back face thereof. The substrate 8 has the trench-shaped recesses 10 formed only in the wiring portions for plating 5 including the partition lines 9 in the periphery of each semiconductor package substrate 1.

Next, as shown in FIG. 5B, semiconductor chips 13 are bonded on the semiconductor chip mounting region 2 on the semiconductor package substrate 1 using a conductive resin or insulating resin, such as epoxy and polyimide. The semiconductor chips 13 are bonded on all the semiconductor package substrates 1 formed in the substrate 8.

Then, as shown in FIG. 5B, the electrodes of the semiconductor chips 13 are electrically connected to the internal electrodes 3 formed on the semiconductor package substrate 1 by a wire bonding method using bonding wires 14 consisting of Au, Cu, Al, and the like. The diameter of the bonding wire 14 is about 10 to 30 μm. The heating temperature for wire bonding is about 100 to 250° C. At this time, since the surfaces of the internal electrodes 3 have been subjected to Au plating, favorable bondability can be obtained.

Next, as shown in FIG. 5C, the entire semiconductor package substrate 1 is encapsulated by a molding resin 15. The thickness of the molding resin 15 is about 0.1 to 0.8 mm on the semiconductor chip 13. At this time, the molding resin 15 is filled also in the trench-shaped recesses 10 formed in the semiconductor package substrate 1.

Next, as shown in FIG. 5D, the substrate 8 and the molding resin 15 are divided by the partition lines 9 by cutting the substrate 8 and the molding resin 15 in the state of FIG. 5C along the partition lines 9 using a dicing saw and the like, to obtain a plurality of semiconductor devices wherein the semiconductor chip 13 is molded with the molding resin 15 on the semiconductor package substrate 1.

At this time, by shortening the thin regions composed of the recesses 10 on the peripheral portion of the semiconductor package substrate 1 to about not more than 0.1 mm from the periphery, a semiconductor device having high mechanical strength can be obtained.

In the semiconductor device manufactured thus, as shown in FIG. 6, the conductor portions such as wirings for plating are not exposed on the side of the semiconductor device, unlike conventional semiconductor devices. Therefore, since there are no short-circuiting between conductor portions and no migration defects due to the conductor portions, and the conductor portions are not touched during handling in the test, there is no contact between adjoining conductor wirings due to the deformation of the conductor portions, and highly reliable semiconductor devices can be obtained.

Although the wire bonding method is used for electrical connection of semiconductor chips 13 in the described embodiment, the present embodiment can also be applied to the case of using connection by flip chip bonding.

What is claimed is:

1. A substrate comprising a plurality of semiconductor package substrates on the surface of which electrically connected internal electrodes and semiconductor chip mounting regions for mounting conductor wirings and semiconductor chips are formed; wherein recesses are formed on the periphery of each semiconductor package substrate, the internal electrodes are electrically insulated from the conductor wirings between the individual semiconductor package substrates; and
the recesses are formed in a trench shape except on the corner portions of the peripheries of the semiconductor package substrates.

2. A substrate comprising a plurality of semiconductor package substrates on the surface of which electrically connected internal electrodes and semiconductor chip mounting regions for mounting conductor wirings and semiconductor chips are formed; wherein recesses are formed on the periphery of each semiconductor package substrate, the internal electrodes are electrically insulated from the conductor wirings between the individual semiconductor package substrates; and
the recesses are independently formed for each of the conductor wirings on the peripheries of the semiconductor package substrates.

3. The substrate according to claim 1 wherein the end portion of at least one of the conductor wirings is extended to the side of the recess.

4. The substrate according to claim 1 wherein the depth of the recesses is not more than ½ of the thickness of the semiconductor package substrate.

5. The substrate according to claim 1 wherein the width of the recesses is not more than 300 μm.

6. A semiconductor device wherein semiconductor chips are mounted in semiconductor chip mounting regions on a substrate comprising a plurality of semiconductor package substrates on the surface of which electrically connected internal electrodes and semiconductor chip mounting regions for mounting conductor wirings and semiconductor chips are formed; the electrodes of the semiconductor chips are electrically connected to the internal electrodes; thin portions are formed on the periphery of each of the semiconductor package substrates; all the regions including at least the thin portions other than the semiconductor chip mounting regions in the semiconductor package substrates are coated with a molding resin; and
the thin portions are formed in a trench shape except on the corner portions in the peripheries of the semiconductor package substrate.

7. A semiconductor device wherein semiconductor chips are mounted in semiconductor chip mounting regions on a substrate comprising a plurality of semiconductor package substrates on the surface of which electrically connected internal electrodes and semiconductor chip mounting regions for mounting conductor wirings and semiconductor chips are formed; the electrodes of the semiconductor chips are electrically connected to the internal electrodes; thin portions are formed on the periphery of each of the semiconductor package substrates; all the regions including at least the thin portions other than the semiconductor chip mounting regions in the semiconductor package substrates are coated with a molding resin; and
the thin portions are independently formed for each of the conductor wirings on the peripheries of the semiconductor package substrates.

8. The semiconductor device according to claim 6 wherein the end portion of at least one of the conductor wirings is extended to the side of the thin portion.

9. The semiconductor device according to claim 6 wherein the depth of the thin portion is not more than ½ of the thickness of the semiconductor package substrate.

10. The semiconductor device according to claim 6 wherein the length from the peripheral portion of the thin portion is not more than 100 μm.

11. The semiconductor device according to claim 6 wherein the electrode of the semiconductor chip and the internal electrode are connected by thin metal wires, and the semiconductor chip and the thin metal wires are coated with the molding resin.

12. The semiconductor device according to claim 6 wherein the electrode of the semiconductor chip and the internal electrode are connected by flip chip bonding.

13. The semiconductor device according to claim 6 wherein the electrode of the semiconductor chip and the internal electrode are connected by flip chip bonding, and are coated with the molding resin.
